(19) United States
(12) Patent Application Publication
(10) Pub. No.: US 2012/0037999 A1
(43) Pub. Date: Feb. 16, 2012

(54) DIFFERENTIAL STOICHIOMETRIES BY INFUSION THRU GCIB FOR MULTIPLE WORK FUNCTION METAL GATE CMOS

(75) Inventors: Hemanth Jagannathan, Guilderland, NY (US); Sivananda K. Kanakasabapathy, Niskayuna, NY (US)

(73) Assignee: International Business Machines Corporation, Armonk, NY (US)

(21) Appl. No.: 12/857,108

(22) Filed: Aug. 16, 2010

(51) Int. Cl. H01L 27/092; H01L 21/28

(52) U.S. Cl. 257/369; 438/585; 257/E21.19; 257/E27.062

(57) ABSTRACT

A method of modulating the work function of a metal layer in a localized manner is provided. Metal gate electrodes having multiple work functions may then be formed from this metal layer. Although the metal layer and metal gate electrodes over both the nFET and pFET regions of the instant substrates are made from only a single metal, they exhibit different electrical performances. The variation of electrical performances is achieved by infusing stoichiometrically-altering atoms into the metal layer, from which the metal gate electrodes are made, via a Gas Cluster Ion Beam process. The resulting metal gate electrodes have the necessary threshold voltages for both nFET and pFET, and are ideal for use in CMOS devices.

### TECHNICAL FIELD

The present disclosure generally relates to CMOS semiconductor transistors and circuits, and more particularly to CMOS transistors having dual work function metal gate electrodes, and methods of manufacturing the same.

### BACKGROUND OF THE DISCLOSURE

Integrated circuits can include millions of components (e.g., transistors, capacitors and resistors) on a single chip. The evolution of chip designs continually requires faster circuitry and greater circuit density. A reduction in the dimensions of integrated circuit components is therefore necessary to achieve greater circuit density.

Utilization of metal gate electrodes has become increasingly attractive as CMOS technology continues to scale beyond the 45 nanometer node because of their many advantages over polycrystalline Si gates. Specifically, metal gate electrodes reduce the poly-depletion effect, reduce sheet resistance, and enable potentially better thermal stability on high-k gate dielectrics. Application of metal gate electrodes is challenging, however it is necessary, because of the need for different electrical performances by different transistors formed in various regions of an integrated circuit. For instance, it is often desirable to have different Threshold Voltages (Vt) between NMOS and PMOS devices, and further diversification within the various types of NMOS and PMOS devices. The different electrical performance requirements have often necessitated that two metallic materials with different work functions be employed to achieve the right threshold voltages for both nFET and pFET. In particular, a low work function metal having a work function of about 4.0 eV is necessary for nFETs while a high work function metal having a work function of about 5.0 eV is necessary for pFETs.

One straightforward process for providing CMOS devices with dual metal gate electrodes includes depositing a first gate metal and then selectively removing the first gate metal from either the nFET or pFET region. After removal of the first gate metal from either the nFET or pFET region, a second gate metal is deposited over the entire wafer and then the nFET and pFET gate electrodes are patterned. Unfortunately, this approach exposes the gate dielectric to a metal-etching process in the region from which the first gate metal is selectively removed, and consequently causes undesirable thinning of the gate dielectric and potential reliability problems. The presence of disparate metals and disparate thicknesses also presents process control and manufacturing challenges during the etching of these heterogeneous films in gate-first patterning schemes. It would therefore be desirable to provide a method of modulating the work function of a metal layer, made from a single metal, to provide multiple work function metal gate electrodes within a CMOS device.

### SUMMARY OF THE DISCLOSURE

Accordingly, the present disclosure provides a method of modulating the work function of a metal layer, from which metal gate electrodes having multiple work functions may be formed, as well as a CMOS device comprising the metal layer or metal gate electrodes having multiple work functions. The work function of the metal layer of the present disclosure is modulated by utilizing a Gas Cluster Ion Beam (GCIB) impact process to infuse stoichiometry-altering atoms into a metal layer over a pFET and/or an nFET region. The resulting pFET and nFET regions have different concentrations of the stoichometry-altering atoms, and/or have metal layers that exhibit different stoichiometries from one another, and thus they exhibit different electrical performances.

One aspect of the present disclosure is a method of modulating a work function of a metal layer comprising:
(A) providing a silicon substrate having an nFET region, a pFET region, a shallow trench isolation (STI) region separating the nFET region of the substrate from the pFET region of the substrate, and a high-k dielectric layer over a top surface of the silicon substrate;
(B) depositing a metal layer over the nFET region and the pFET region;
(C) applying a mask over the nFET and the pFET regions and lithographically patterning the mask to cover the nFET region, while exposing the pFET region;
(D) performing gas cluster ion beam processing to infuse a mixture of stoichiometry-altering atoms and an inert gas into the metal layer deposited over the pFET region; and
(E) removing the mask from the nFET region.

A second aspect of the present disclosure is a method of modulating a work function of a metal layer comprising:
(A) providing a silicon substrate having an nFET region, a pFET region, a shallow trench isolation (STI) region separating the nFET region of the substrate from the pFET region of the substrate, and a high-k dielectric layer over a top surface of the silicon substrate;
(B) depositing a metal layer over the nFET region and the pFET region;
(C) applying a mask over the nFET and the pFET regions and lithographically patterning the mask to cover the nFET region, while exposing the pFET region;
(D) performing gas cluster ion beam processing to infuse a mixture of stoichiometry-altering atoms and an inert gas into the metal layer deposited over the pFET region;
(E) removing the mask from the nFET region;
(F) applying a mask over the nFET and the pFET regions and lithographically patterning the mask to cover the pFET region, while exposing the nFET region;
(G) performing gas cluster ion beam processing to infuse a mixture of stoichiometry-altering atoms and an inert gas into the metal layer deposited over the nFET region; and
(H) removing the mask from the pFET region.

After this process has been performed, gate electrodes can be patterned and etched from the infused metal layer that was deposited over the nFET and pFET regions according to methods well known in the art.

Yet another aspect of the present disclosure is a method of modulating a work function of a metal layer comprising:
(A) providing a silicon substrate having an nFET region, a pFET region, a shallow trench isolation (STI) region separating the nFET region of the substrate from the pFET region of the substrate, and a high-k dielectric layer over a top surface of the silicon substrate;
(B) depositing a metal layer over the nFET region and the pFET region;
(C) applying a mask over the nFET and the pFET regions and lithographically patterning the mask to cover the pFET region, while exposing the nFET region;
(D) performing gas cluster ion beam processing to infuse a mixture of stoichiometry-altering atoms and an inert gas into the metal layer deposited over the nFET region; and
(E) removing the mask from the pFET region.

A fourth aspect of the present disclosure is a method of modulating a work function of a metal layer comprising:
(A) providing a silicon substrate having an nFET region, a pFET region, a shallow trench isolation (STI) region separating the nFET region of the substrate from the pFET region of the substrate, and a high-k dielectric layer over a top surface of the silicon substrate;
(B) depositing a metal layer over the nFET region and the pFET region;
(C) applying a mask over the nFET and the pFET regions and lithographically patterning the mask to cover the pFET region, while exposing the nFET region;
(D) performing gas cluster ion beam processing to infuse a mixture of stoichiometry-altering atoms and an inert gas into the metal layer deposited over the nFET region;
(E) removing the mask from the pFET region;
(F) applying a mask over the nFET and the pFET regions and lithographically patterning the mask to cover the nFET region, while exposing the pFET region;
(G) performing gas cluster ion beam processing to infuse a mixture of stoichiometry-altering atoms and an inert gas into the metal layer deposited over the pFET region; and
(H) removing the mask from the nFET region.

After this process has been performed, gate electrodes can be patterned and etched from the infused metal layer that was deposited over the nFET and pFET regions according to methods well known in the art.

In all of the above methods, the metal layer that is deposited over the nFET and pFET regions comprises TiN, TaN, WN, TiAlN, TaC, or TaCN, and has a thickness of between about 5 Angstroms and about 100 Angstroms. The stoichiometry-altering atoms typically comprise N₂, O₂, Cl₂ or F₂, or are a liquid precursor comprising at least one element of La, Al, Co, Ni, Ta, or Ti, wherein the element is not readily volatile in its native state. The inert gases that may be employed in any of the above methods are He, Ar, Ne, Kr, or Xe.

After the processes described above are performed, a capping layer may optionally be added over the top of the metal layer over the pFET and nFET regions. This capping layer typically comprises TiN, TaN, WN, TiAlN, TaC, or TaCN, and can be deposited using any known method in the art including chemical vapor deposition (CVD), atomic layer deposition (ALD), physical vapor deposition (PVD), molecular beam epitaxy (MBE), pulsed laser deposition (PLD), or liquid source misted chemical deposition (LSMCD). Furthermore, thermal treatments such as laser or rapid thermal annealing may optionally be performed after GCIB processing of an individual metal layer has been performed to facilitate or further enhance the modulation of the metal layers' work functions.

The infusion of stoichiometry-altering atoms into the metal layer over the nFET region and into the metal layer over the pFET region during GCIB processing may cause a change in the stoichiometry of the metal layer over these regions of between about 0.1% and about 10% as compared to the pre-infusion stoichiometry. Alternatively, GCIB processing may cause a concentration of stoichiometry-altering atoms in the metal layer over the nFET region and the metal layer over the pFET region to change by about 0.1% to about 10% as compared to the pre-infusion concentration. In either case, the change in the metal layer over the pFET region is independent of the change in the metal layer over the nFET region. Typically, the methods of the instant disclosure enable the threshold voltages of the metal layer over the nFET and pFET regions to be modulated by about ±500 millivolts, and more typically by about ±30-50 millivolts.

Yet another aspect of the present disclosure is a CMOS device comprising the metal layer or the metal gate electrodes produced by any of the methods described above.

### BRIEF DESCRIPTION OF THE DRAWINGS

FIG. 1 is a pictorial representation (through a cross-sectional view) of a silicon substrate utilized in the methods of the present disclosure having an nFET region, a pFET region, and a shallow trench isolation (STI) region separating the nFET region of the substrate from the pFET region of the substrate.

FIG. 2 is a pictorial representation (through a cross-sectional view) of the substrate of FIG. 1 after a single metal layer has been deposited over the nFET and pFET regions of the substrate.

FIG. 3 is a pictorial representation (through a cross-sectional view) of the substrate of FIG. 2 after the nFET region has been masked.

FIG. 4 is a pictorial representation (through a cross-sectional view) of the substrate of FIG. 3 during the gas cluster ion beam processing step of the methods of the present disclosure.

FIG. 5 is a pictorial representation (through a cross-sectional view) of the substrate of FIG. 4 after the mask over the nFET region has been removed.

FIG. 6 is a pictorial representation (through a cross-sectional view) of the substrate utilized in the methods of the present disclosure after the pFET region has been masked.

FIG. 7 is a pictorial representation (through a cross-sectional view) of the substrate of FIG. 6 during the gas cluster ion beam processing step of the methods of the present disclosure.

FIG. 8 is a pictorial representation (through a cross-sectional view) of the substrate of FIG. 7 after the mask over the pFET region has been removed.

FIG. 9 is a pictorial representation (through a cross-sectional view) of the substrate of FIG. 8 after the gate electrodes are patterned and etched.

### DESCRIPTION OF BEST AND VARIOUS EMBODIMENTS OF DISCLOSURE

The present disclosure, which is directed to a method of modulating the work function of a metal layer, from which metal gate electrodes having multiple work functions may be formed, and a CMOS device comprising the metal gate electrodes, will now be described in greater detail by referring to the drawings that accompany the present application. It is noted that in the accompanying drawings, like reference numerals are used for describing like and/or corresponding elements.

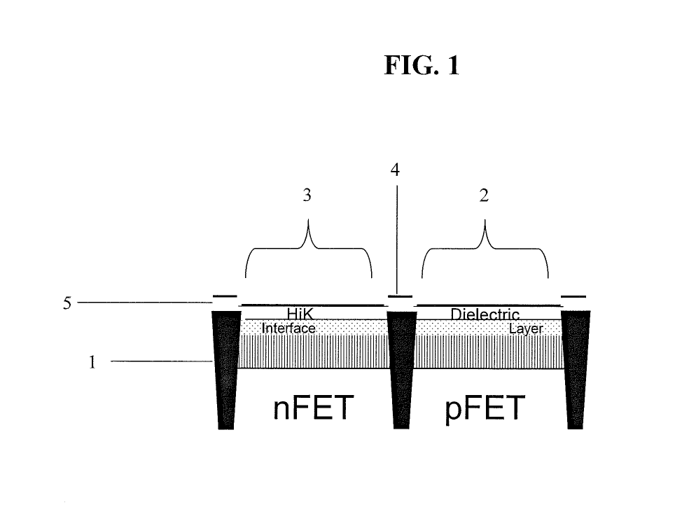

Reference is first made to FIGS. 1-9 which illustrate the basic processing steps of the present disclosure that are capable of forming a CMOS device comprising multiple work function metal gate electrodes made from a single metal. FIG. 1 demonstrates the first step of providing a substrate 1 having a pFET region 2, an nFET region 3, a shallow trench isolation (STI) region 4 separating the nFET region 3 of the substrate from the pFET region 2, and a high-k dielectric layer 5. The substrate 1 may be a bulk substrate, a semiconductor-on-insulator (SOI) substrate, or a hybrid substrate. The high-k dielectric layer 5 is formed over a top surface of the substrate 1, or over a top interface layer, by methods well known in the art including chemical vapor deposition (CVD), atomic layer deposition (ALD), physical vapor deposition (PVD), molecular beam epitaxy (MBE), pulsed laser deposition (PLD), or liquid source misted chemical deposition (LSMCD).

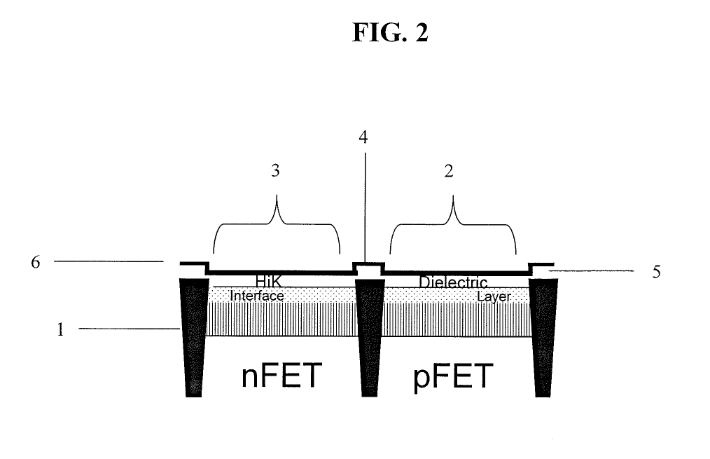

After the appropriate substrate is provided, FIG. 2 illustrates the substrate of FIG. 1 after a single metal layer 6 has been deposited over the nFET region 3 and pFET region 2. The metal layer 6 typically comprises TiN, TaN, WN, TiAlN, TaC, or TaCN and may be formed, for example, by atomic layer deposition (ALD), physical vapor deposition (PVD), chemical vapor deposition, sputtering, or any other suitable method known in the art. This metal layer 6 typically has a thickness between about 5 Angstroms and about 100 Angstroms.

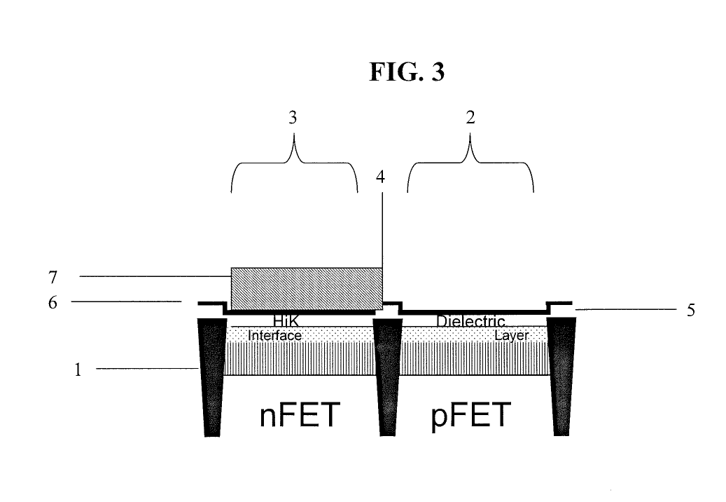

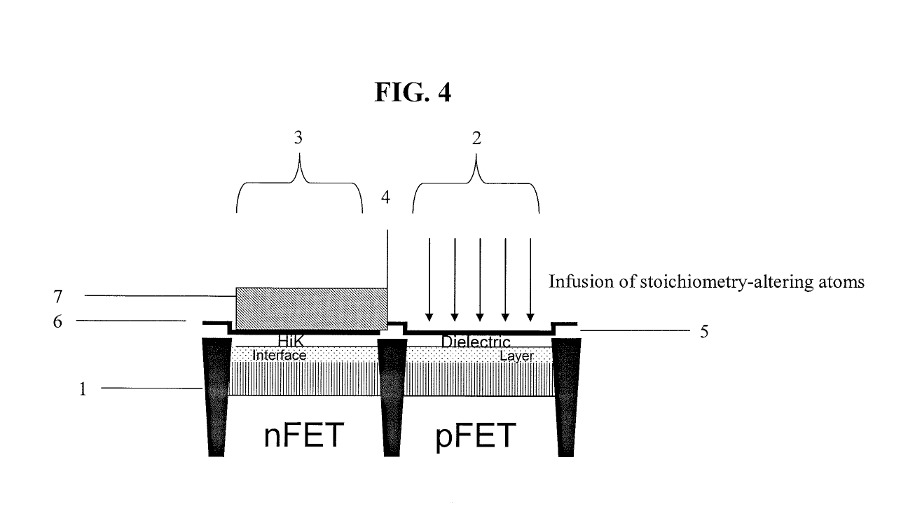

Next, FIG. 3 shows the substrate of FIG. 2 after the nFET region 3 has been masked. During this step of the process, a mask 7 is applied over the nFET and the pFET regions and lithographically patterned to cover the nFET region, while exposing the pFET region 2. After the pFET region 2 is exposed, FIG. 4 illustrates the infusion of stoichiometry-altering atoms admixed with one or more inert gases into the metal layer 6 over the pFET region 2 using GCIB. Typically, stoichiometry-altering atoms comprise N₂, O₂, Cl₂ or F₂, or comprise a liquid precursor comprising at least one element of La, Al, Co, Ni, Ta, or Ti, wherein the element is not readily volatile in its native state. These stoichiometry-altering atoms are infused into the pFET region 2, and an inert gas comprising He, Ar, Ne, Kr, or Xe is admixed with the stoichiometry-altering atoms.

GCIB has been used extensively in the art for dry etching, cleaning, and smoothing of hard materials, and has been described by, for example, Deguchi, et al. in U.S. Pat. No. 5,814,194, “Substrate Surface Treatment Method,” 1998. Moreover, methods of using GCIB to infuse material, such as stoichiometry-altering atoms, into a substrate are well known in the art. Indeed, such methods are described in, for example, U.S. patent application Ser. No. 12/020,094 (Publication No. 20090191696), which is incorporated by reference herein in its entirety. During GCIB, ionized clusters containing on the order of thousands of gas atoms or molecules may be formed and accelerated to modest energies on the order of a few thousand electron volts. Individual atoms or molecules in the clusters each only have an average energy on the order of a few electron volts. Employment of GCIB in the method of the present disclosure is therefore advantageous because the stoichiometric-altering atoms used only penetrate through a few monolayers, at most, of a target surface during impact. Therefore, the stoichiometric-altering atoms infuse only the desired layers of a device being processed.

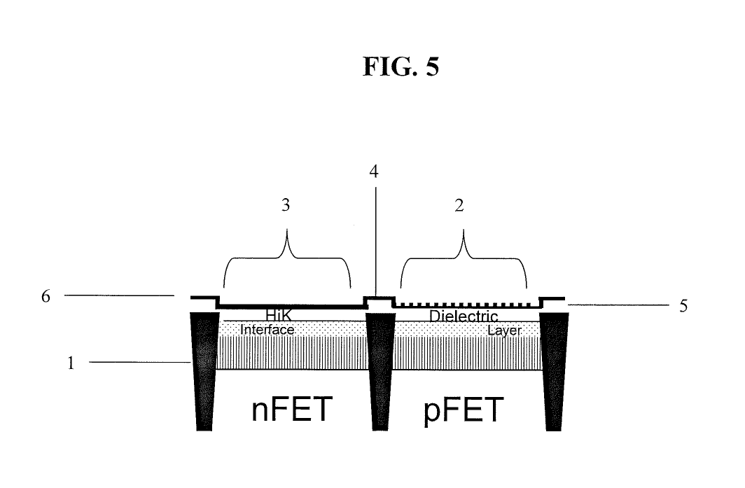

Once the GCIB processing of the pFET region 2 is completed, the masking layer 7 is removed from the nFET region 3 to yield the structure of FIG. 5.

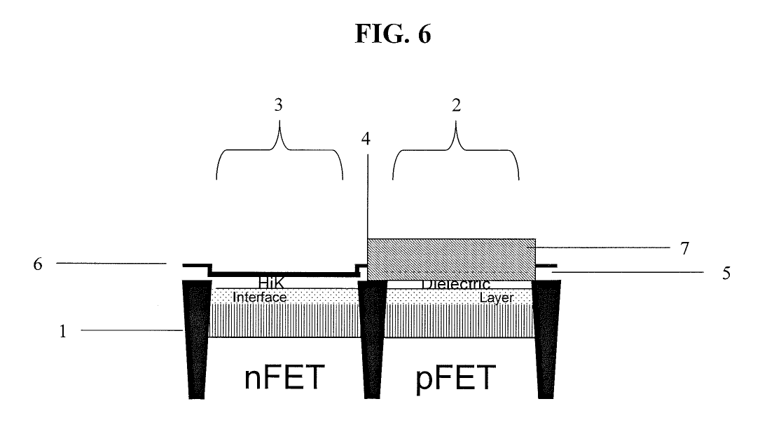

Next, FIG. 6 shows the substrate of FIG. 5 after the pFET region 2 has been masked. During this step, a mask 7 is applied over the nFET and pFET regions and lithographically patterned to cover the pFET region 2 while exposing the nFET region 3.

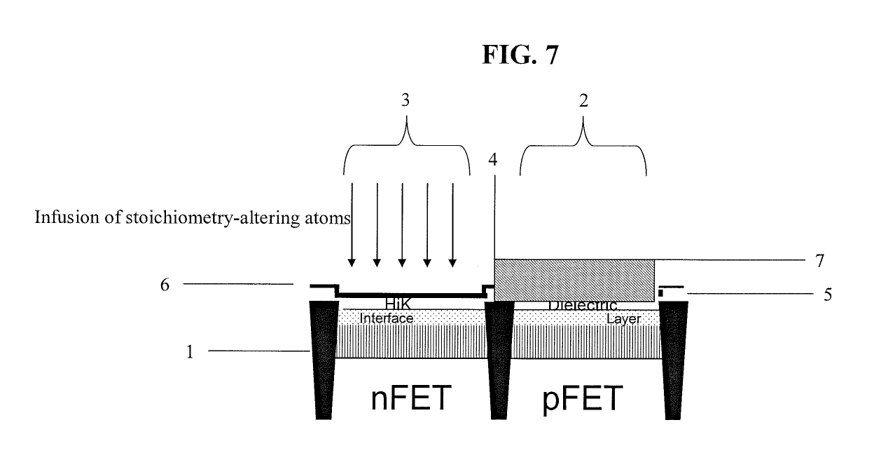

After the nFET region 3 is exposed, FIG. 7 illustrates the infusion of stoichiometry-altering atoms admixed with one or more inert gases into the metal layer 6 over the nFET region 3 using gas cluster ion beam impact (GCIB). Typically, the stoichiometry-altering atoms comprise N₂, O₂, Cl₂ or F₂, or are a liquid precursor comprising at least one element of La, Al, Co, Ni, Ta, or Ti, wherein the element is not readily volatile in its native state. These stoichiometry-altering atoms, which are admixed with an inert gas comprising He, Ar, Ne, Kr, or Xe, are infused into the metal layer 6 over the nFET region 3.

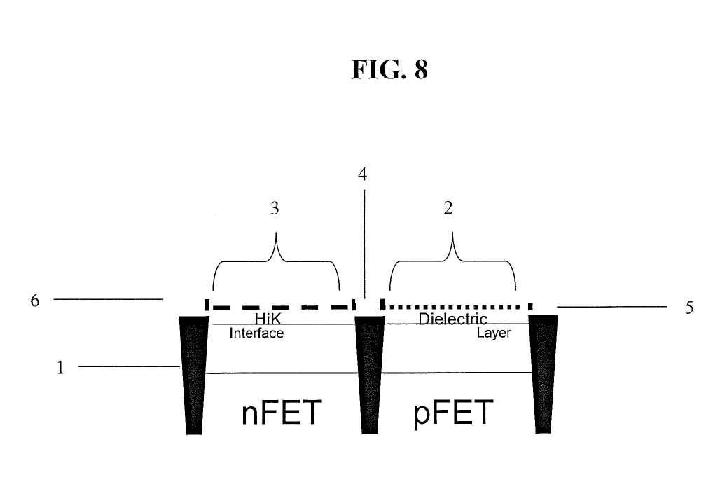

Once the GCIB processing of the nFET region 3 is completed, the masking layer 7 is removed from the pFET region 2 to yield the structure of FIG. 8. Next, gate electrodes are patterned and etched from the metal layer 6.

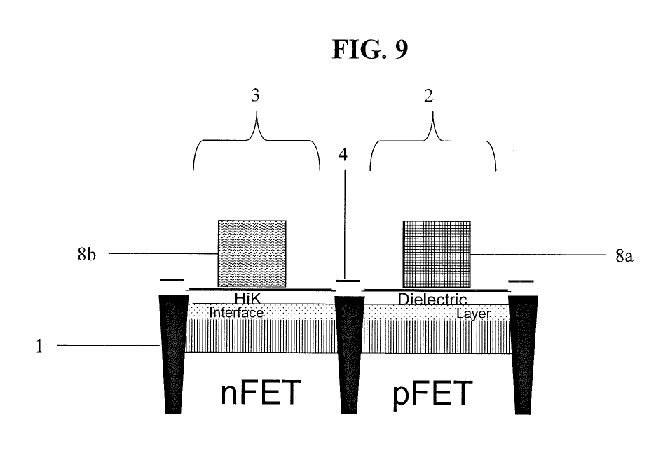

FIG. 9 illustrates the substrate after the gate electrodes 8a and 8b are patterned and etched from the metal layer 6. Gate electrodes 8a and 8b exhibit different electrical performances that are ideal for the pFET and nFET regions, respectively.

While bulk CMOS applications require that the metal gates over the pFET region 2 and nFET region 3 have work functions of around 5.0 volts and 4.0 volts, respectively, other applications might require different work function values for optimal circuit performance. Therefore, different amounts of stoichiometry-altering atoms can be infused into each region to optimize the work function therein.

A new method for modulating the work functions of gate electrodes made from a single metal is successfully demonstrated in the specific embodiments of the present disclosure. Still other objects and advantages of the present disclosure will become readily apparent by those skilled in the art from the preceding detailed description, wherein it is shown and described preferred embodiments, simply by way of illustration of the best mode contemplated. As will be realized the disclosure is capable of other and different embodiments, and its several details are capable of modifications in various obvious respects, without departing from the disclosure. Accordingly, the description is to be regarded as illustrative in nature and not as restrictive.

The term “comprising” (and its grammatical variations) as used herein is used in the inclusive sense of “having” or “including” and not in the exclusive sense of “consisting only of.” The term “consisting essentially of” as used herein is intended to refer to including that which is explicitly recited along with what does not materially affect the basic and novel characteristics of that recited or specified. The terms “a” and “the” as used herein are understood to encompass the plural as well as the singular.

What is claimed is:

1. A method of modulating a work function of a metal layer comprising:
(A) providing a silicon substrate having an nFET region, a pFET region, a shallow trench isolation (STI) region separating the nFET region of the substrate from the pFET region of the substrate, and a high-k dielectric layer over a top surface of the silicon substrate;
(B) depositing a metal layer over the nFET region and the pFET region;
(C) applying a mask over the nFET and the pFET regions and lithographically patterning the mask to cover the nFET region, while exposing the pFET region;
(D) performing gas cluster ion beam processing to infuse a mixture of stoichiometry-altering atoms and an inert gas into the metal layer deposited over the pFET region; and
(E) removing the mask from the nFET region.

2. The method according to claim 1, wherein
the metal layer comprises TiN, TaN, WN, TiAlN, TaC, or TaCN;
the inert gas comprises He, Ar, Ne, Kr, or Xe; and
the stoichiometry-altering atoms comprise N₂, O₂, Cl₂ or F₂, or are a liquid precursor comprising at least one element of La, Al, Co, Ni, Ta, or Ti, wherein the element is not volatile in its native state.

3. The method according to claim 1, further comprising:
(A) applying a mask over the nFET and the pFET regions and lithographically patterning the mask to cover the pFET region, while exposing the nFET region;
(B) performing gas cluster ion beam processing to infuse a mixture of stoichiometry-altering atoms and an inert gas into the metal layer deposited over the nFET region; and
(C) removing the mask from the pFET region.

4. The method according to claim 3, further comprising depositing a capping layer over the metal layer over the nFET and pFET regions after the mask is removed from the pFET region.

5. The method according to claim 3, further comprising thermally treating the metal layer over the nFET region and/or the metal layer over the pFET region after gas cluster ion beam processing is completed.

6. The method according to claim 3, further comprising:
(A) forming a gate electrode structure from the metal layer deposited over the nFET region; and
(B) forming a gate electrode structure from the metal layer deposited over the pFET region
after the mask is removed from the pFET region.

7. The method according to claim 3, wherein
the metal layer comprises TiN, TaN, WN, TiAlN, TaC, or TaCN;
the inert gas comprises He, Ar, Ne, Kr, or Xe; and
the stoichiometry-altering atoms comprise N₂, O₂, Cl₂ or F₂, or are a liquid precursor comprising at least one element of La, Al, Co, Ni, Ta, or Ti,
wherein the element is not volatile in its native state.

8. The method according to claim 3, wherein a stoichiometry of the metal layer over the nFET region, and a stoichiometry of the metal layer over the pFET region, changes, independently of one another, by about 0.1% to about 10% during the gas cluster ion beam processing.

9. The method according to claim 3, wherein a concentration of stoichiometry-altering atoms in the metal layer over the nFET region, and a concentration of stoichiometry-altering atoms in the metal layer over the pFET region, changes, independently of one another, by about 0.1% to about 10% during the gas cluster ion beam processing.

10. A method of modulating a work function of a metal layer comprising:
(A) providing a silicon substrate having an nFET region, a pFET region, a shallow trench isolation (STI) region separating the nFET region of the substrate from the pFET region of the substrate, and a high-k dielectric layer over a top surface of the silicon substrate;
(B) depositing a metal layer over the nFET region and the pFET region;
(C) applying a mask over the nFET and the pFET regions and lithographically patterning the mask to cover the pFET region, while exposing the nFET region;
(D) performing gas cluster ion beam processing to infuse a mixture of stoichiometry-altering atoms and an inert gas into the metal layer deposited over the nFET region; and
(E) removing the mask from the pFET region.

11. The method according to claim 10, wherein
the metal layer comprises TiN, TaN, WN, TiAlN, TaC, or TaCN;
the inert gas comprises He, Ar, Ne, Kr, or Xe; and
the stoichiometry-altering atoms comprise N₂, O₂, Cl₂ or F₂, or are a liquid precursor containing at least one element of La, Al, Co, Ni, Ta, or Ti, wherein the element is not volatile in its native state.

12. The method according to claim 10, further comprising:
(A) applying a mask over the nFET and the pFET regions and lithographically patterning the mask to cover the nFET region, while exposing the pFET region;
(B) performing gas cluster ion beam processing to infuse a mixture of stoichiometry-altering atoms and an inert gas into the metal layer deposited over the pFET region; and
(C) removing the mask from the nFET region.

13. The method according to claim 12, further comprising depositing a capping layer over the metal layer over the nFET and pFET regions after the mask is removed from the nFET region.

14. The method according to claim 12, further comprising thermally treating the metal layer over the nFET region and/or the metal layer over the pFET region after gas cluster ion beam processing is completed.

15. The method according to claim 12, further comprising:
(A) forming a gate electrode structure from the metal layer deposited over the nFET region; and
(B) forming a gate electrode structure from the metal layer deposited over the pFET region
after the mask is removed from the nFET region.

16. The method according to claim 12, wherein
the metal layer comprises TiN, TaN, WN, TiAlN, TaC, or TaCN;
the inert gas comprises He, Ar, Ne, Kr, or Xe; and
the stoichiometry-altering atoms comprise N₂, O₂, Cl₂ or F₂, or are a liquid precursor comprising at least one element of La, Al, Co, Ni, Ta, or Ti,
wherein the element is not volatile in its native state.

17. The method according to claim 12, wherein a stoichiometry of the metal layer over the nFET region, and a stoichiometry of the metal layer over the pFET region, changes, independently of one another, by about 0.1% to about 10% during the gas cluster ion beam processing.

18. The method according to claim 12, wherein a concentration of stoichiometry-altering atoms in the metal layer over the nFET region, and a concentration of stoichiometry-altering atoms in the metal layer over the pFET region, changes, independently of one another, by about 0.1% to about 10% during the gas cluster ion beam processing.

19. A CMOS device comprising the metal layer produced by the method of claim 1.

20. A CMOS device comprising the metal layer produced by the method of claim 3.

21. A CMOS device comprising the gate electrode structures produced by the method of claim 6.

22. A CMOS device comprising the metal layer produced by the method of claim 10.

23. A CMOS device comprising the metal layer produced by the method of claim 12.

24. A CMOS device comprising the gate electrode structures produced by the method of claim 15.
